(19) United States
(12) Patent Application Publication
(10) Pub. No.: US 2023/0118423 A1
(43) Pub. Date: Apr. 20, 2023

(54) POSITION DETECTOR

(71) Applicant: Murata Manufacturing Co., Ltd., Nagaokakyo-shi (JP)

(72) Inventors: Daisuke NAKAMURA, Nagaokakyo-shi (JP); Takuya SUGIMOTO, Nagaokakyo-shi (JP); Yoshihiro ITO, Nagaokakyo-shi (JP)

(21) Appl. No.: 18/082,631

(22) Filed: Dec. 16, 2022

Related U.S. Application Data
(63) Continuation of application No. PCT/JP2021/020599, filed on May 31, 2021.

(30) Foreign Application Priority Data
Jul. 3, 2020 (JP) 2020-115266

(51) Int. Cl. G01D 5/16; G01R 33/09; G02B 26/08; H04N 23/55

(52) U.S. Cl. CPC G01D 5/16; G01R 33/091; G02B 26/08; H04N 23/55

(57) ABSTRACT

A magnetic sensor is able to detect a magnetic field applied from a position detecting magnet that makes relative movement as an optical reflector is rotated. Rotation of the optical reflector enables the position detecting magnet to pass through a reference position where a rotation axis, a center or approximate center of the magnetic sensor, and a center or approximate center of the position detecting magnet are located in order on a straight line, as seen in the axial direction of the rotation axis. The magnetic sensor is in an XZ plane that includes a magnetization direction passing through the center or approximate center of the position detecting magnet located at the reference position, and the axial direction of the rotation axis.

### CROSS REFERENCE TO RELATED APPLICATIONS

This application claims the benefit of priority to Japanese Patent Application No. 2020-115266 filed on Jul. 3, 2020 and is a Continuation Application of PCT Application No. PCT/JP2021/020599 filed on May 31, 2021. The entire contents of each application are hereby incorporated herein by reference.

### BACKGROUND OF THE INVENTION

### 1. Field of the Invention

The present invention relates to a position detector.

### 2. Description of the Related Art

US2018/0188476A1 discloses a configuration of a position detector. The position detector disclosed in US2018/0188476A1 includes a fixed member, a movable member, an optical element, a position detecting magnet, and a magnetic sensor. The movable member is movably connected to the fixed member. The optical element is disposed on the movable member. The position detecting magnet corresponds to the optical element and has a magnetization direction. The magnetic sensor corresponds to the position detecting magnet and detects rotation of the position detecting magnet around an axis relative to the fixed member. The axis is perpendicular to the magnetization direction of the position detecting magnet.

The position detector disclosed in US2018/0188476A1 still has room for improvement in the position detection range and the position detection accuracy with a simple configuration.

### SUMMARY OF THE INVENTION

Preferred embodiments of the present invention provide position detectors that are each able to improve the position detection range and the position detection accuracy with a simple configuration.

A position detector according to a preferred embodiment of the present invention includes an optical reflector, a position detecting magnet, and a magnetic sensor. The optical reflector is rotatable about a rotation axis. The position detecting magnet is located on the optical reflector. The position detecting magnet has a magnetization direction orthogonal or substantially orthogonal to an axial direction of the rotation axis. The magnetic sensor is fixed. The magnetic sensor is operable to detect a magnetic field applied from the position detecting magnet that makes relative movement as the optical reflector is rotated. Rotation of the optical reflector enables the position detecting magnet to pass through a reference position where the rotation axis, a center or approximate center of the magnetic sensor, and a center or approximate center of the position detecting magnet are located in order on a straight line, as seen in the axial direction. The magnetic sensor is in a plane that includes the magnetization direction passing through the center or approximate center of the position detecting magnet located at the reference position, and the axial direction.

According to preferred embodiments of the present invention, the position detection range and the position detection accuracy can be improved with a simple configuration.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a side view showing a configuration of a compact camera module including a position detector according to Preferred Embodiment 1 of the present invention.

FIG. 2 shows a state in which an optical reflector is rotated in one direction about a rotation axis, in the compact camera module of FIG. 1.

FIG. 3 shows a state in which the optical reflector is rotated in the other direction about the rotation axis, in the compact camera module of FIG. 1.

FIG. 4 is a side view showing, in an enlarged form, a configuration of the position detector in the compact camera module of FIG. 1.

FIG. 5 shows a positional relationship, as seen in the axial direction of the rotation axis, between a position detecting magnet and a magnetic sensor in the position detector according to Preferred Embodiment 1 of the present invention.

FIG. 6 shows a configuration of the magnetic sensor included in the position detector according to Preferred Embodiment 1 of the present invention.

FIG. 7 shows a circuit configuration of the magnetic sensor included in the position detector according to Preferred Embodiment 1 of the present invention.

FIG. 8 is a perspective view showing, in an enlarged view, the portion defined by VIII in FIG. 6.

FIG. 9 is a cross-sectional view along a line IX-IX in FIG. 8 as seen in the direction of the arrows.

FIG. 10 is a graph showing the results of Experimental Example 1.

FIG. 11 is a graph for illustrating an error rate of the output of the magnetic sensor.

FIG. 12 is a graph showing a possible range of each of a rotation angle and L1/L2, depending on a required linearity error rate of the output of the magnetic sensor, in an intended measurement range of the detected angle of the magnetic sensor, according to Experimental Example 1.

FIG. 13 shows a positional relationship, as seen in the axial direction of the rotation axis, between a position detecting magnet and a magnetic sensor in a position detector according to Preferred Embodiment 2 of the present invention.

FIG. 14 is a graph showing the results of Experimental Example 2.

FIG. 15 is a graph showing a possible range of each of the rotation angle and L1/L2, depending on a required linearity error rate of the output of the magnetic sensor, in an intended measurement range of the detected angle of the magnetic sensor, according to Experimental Example 2.

### DETAILED DESCRIPTION OF THE PREFERRED EMBODIMENTS

In the following, position detectors according to preferred embodiments of the present invention are described with reference to the drawings. In the following description of the preferred embodiments, the same or corresponding elements and portions in the drawings are denoted by the same reference characters, and a description thereof is not herein repeated.

### Preferred Embodiment 1

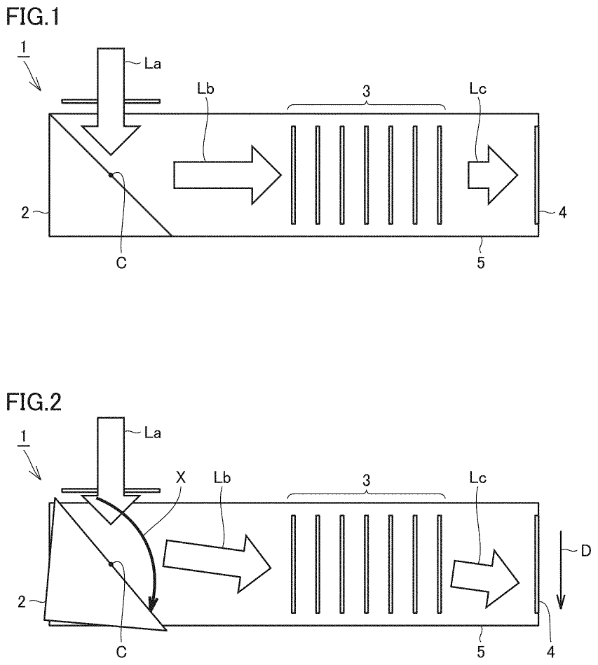

FIG. 1 is a side view showing a configuration of a compact camera module including a position detector according to Preferred Embodiment 1 of the present invention. In FIG. 1, a position detecting magnet and a magnetic sensor that are included in the position detector are not shown.

As shown in FIG. 1, a compact camera module 1 including a position detector according to Preferred Embodiment 1 of the present invention includes an optical reflector 2, an actuator 3 including a group of lenses, an image sensor 4, and a fixed portion 5. Optical reflector 2, actuator 3 including the group of lenses, and image sensor 4 are each arranged along a main surface of fixed portion 5. Compact camera module 1 is, for example, a periscope camera module. In compact camera module 1, optical reflector 2 is rotated to provide a camera shake compensation function, as described later herein.

Optical reflector 2 is rotatable about a rotation axis C. Specifically, optical reflector 2 is, for example, a prism mirror. Optical reflector 2 is rotated about rotation axis C, by being driven by a drive mechanism (not shown). Rotation axis C is orthogonal or substantially orthogonal to the main surface of fixed portion 5. Thus, optical reflector 2 is rotated along the main surface of fixed portion 5.

Light La from the outside of compact camera module 1 is incident on optical reflector 2. Light La reflected from optical reflector 2 is light Lb that travels toward actuator 3 including the group of lenses and passes through the group of lenses. Light Lc having passed through the group of lenses enters image sensor 4.

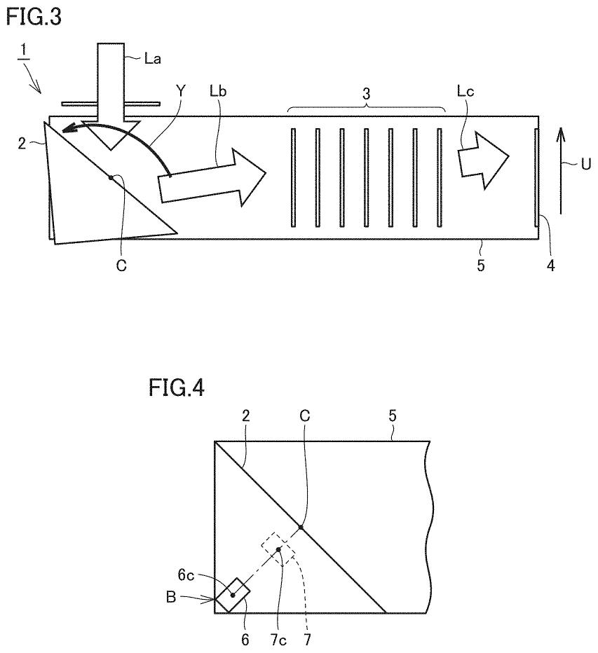

FIG. 2 shows a state in which the optical reflector is rotated in one direction about the rotation axis, in the compact camera module of FIG. 1. FIG. 3 shows a state in which the optical reflector is rotated in the other direction about the rotation axis, in the compact camera of FIG. 1.

As shown in FIG. 2, in the state in which optical reflector 2 is rotated in one direction X about rotation axis C, the incident angle of light Lb to actuator 3 including the group of lenses varies depending on the rotation angle of optical reflector 2. Consequently, the position at which light Lc enters image sensor 4 is shifted in the direction indicated by an arrow D.

As shown in FIG. 3, in the state in which optical reflector 2 is rotated in the other direction Y about rotation axis C, the incident angle of light Lb to actuator 3 including the group of lenses varies depending on the rotation angle of optical reflector 2. Consequently, the position at which light Lc enters image sensor 4 is shifted in the direction indicated by an arrow U.

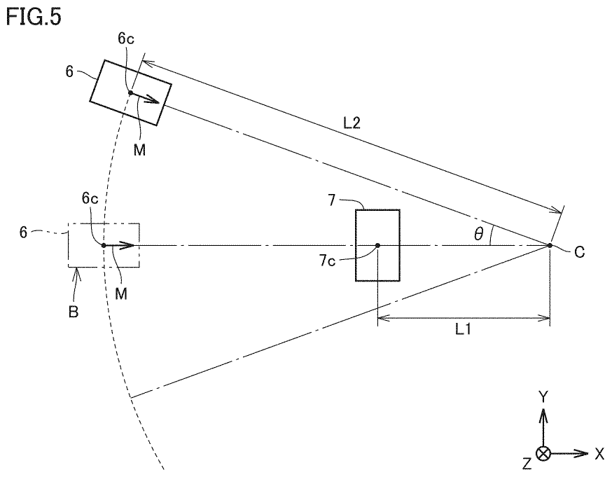

FIG. 4 is a side view showing, in an enlarged view, a configuration of the position detector in the compact camera module of FIG. 1. FIG. 5 shows a positional relationship, as seen in the axial direction of the rotation axis, between a position detecting magnet and a magnetic sensor in the position detector according to Preferred Embodiment 1 of the present invention. In FIG. 5, the direction parallel or substantially parallel to the axial direction of rotation axis C is denoted as Z-axis direction, the direction of a line connecting rotation axis C and a center 6c of a position detecting magnet 6 located at a reference position B, which is described later herein, is denoted as X-axis direction, and the direction orthogonal or substantially orthogonal to each of the X-axis direction and the Z-axis direction is denoted as Y-axis direction.

As shown in FIGS. 4 and 5, the position detector according to Preferred Embodiment 1 of the present invention includes optical reflector 2, position detecting magnet 6, and a magnetic sensor 7. Position detecting magnet 6 is disposed on optical reflector 2. Position detecting magnet 6 is fixed to one side surface, in the Z-axis direction, of optical reflector 2. Magnetic sensor 7 is fixedly disposed. Magnetic sensor 7 is fixed to the main surface of fixed portion 5 that faces the other side surface, in the Z-axis direction, of optical reflector 2.

Specifically, as shown in FIG. 5, the shortest distance between a center 7c of magnetic sensor 7 and rotation axis C, as seen in the axial direction of rotation axis C, is L1. As seen in the axial direction of rotation axis C, the shortest distance between center 6c of position detecting magnet 6 and rotation axis C is L2. In the present preferred embodiment, the relationship L1≤L2 is satisfied. The positional relationship, in the Z-axis direction, between magnetic sensor 7 and position detecting magnet 6 is not particularly limited.

Position detecting magnet 6 is rotated about rotation axis C, together with optical reflector 2. As shown in FIG. 5, as seen in the axial direction of rotation axis C, center 6c of position detecting magnet 6 moves on a rotation trajectory indicated by a dotted line. Rotation of optical reflector 2 enables position detecting magnet 6 to pass through a reference position B where rotation axis C, center 7c of magnetic sensor 7, and center 6c of position detecting magnet 6 are located in order on a straight line, as seen in the axial direction of rotation axis C. The rotation angle, about rotation axis C, of position detecting magnet 6 from reference position B is denoted as θ. In other words, when θ=0, position detecting magnet 6 is located at reference position B.

Magnetization direction M of position detecting magnet 6 is orthogonal or substantially orthogonal to the axial direction of rotation axis C. Specifically, as seen in the axial direction of rotation axis C, magnetization direction M of position detecting magnet 6 is a direction toward rotation axis C. As seen in the axial direction of rotation axis C, the rotation axis C side of position detecting magnet 6 is N pole, and the side opposite to the rotation axis C side of position detecting magnet 6 is S pole.

Magnetic sensor 7 is in a plane that includes magnetization direction M passing through center 6c of position detecting magnet 6 located at reference position B, and the axial direction of rotation axis C. In other words, magnetic sensor 7 is in the XZ plane shown in FIG. 5. Magnetic sensor 7 is capable of detecting a magnetic field applied from position detecting magnet 6 that makes relative movement as optical reflector 2 is rotated. Specifically, magnetic sensor 7 provides its output depending on the detected angle that is the orientation of a magnetic field applied from position detecting magnet 6.

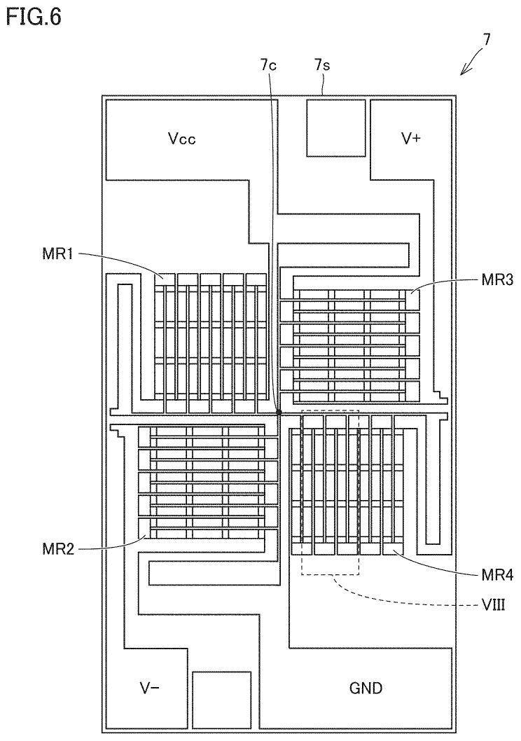

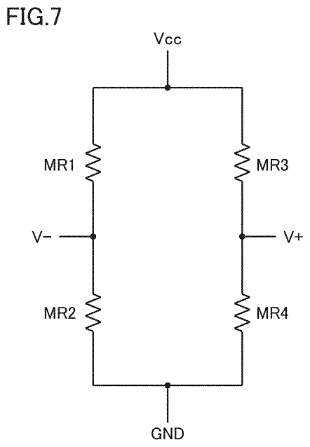

FIG. 6 shows a configuration of the magnetic sensor included in the position detector according to Preferred Embodiment 1 of the present invention. FIG. 7 shows a circuit configuration of the magnetic sensor included in the position detector according to Preferred Embodiment 1 of the present invention. FIG. 6 shows the magnetic sensor as seen in the same direction as FIG. 5.

As shown in FIGS. 6 and 7, magnetic sensor 7 includes a plurality of magnetoresistance effect elements that define a bridge circuit. In Preferred Embodiment 1 of the present invention, magnetic sensor 7 includes a first magnetoresistance effect element MR1, a second magnetoresistance effect element MR2, a third magnetoresistance effect element MR3, and a fourth magnetoresistance effect element MR4.

Specifically, as shown in FIG. 6, in magnetic sensor 7, first magnetoresistance effect element MR1, second magnetoresistance effect element MR2, third magnetoresistance effect element MR3, and fourth magnetoresistance effect element MR4 are each disposed on the upper surface of a sensor substrate 7s. On sensor substrate 7s, a power supply terminal Vcc, a ground terminal GND, a first output terminal V+, and a second output terminal V− are disposed. A magnetic field, to be detected, of position detecting magnet 6 is applied to magnetic sensor 7 in the direction along the upper surface of sensor substrate 7s.

First magnetoresistance effect element MR1, second magnetoresistance effect element MR2, third magnetoresistance effect element MR3, and fourth magnetoresistance effect element MR4 are electrically connected to each other to define a Wheatstone bridge circuit. Magnetic sensor 7 may include a half-bridge circuit defined by first magnetoresistance effect element MR1 and second magnetoresistance effect element MR2.

Series-connected first magnetoresistance effect element MR1 and second magnetoresistance effect element MR2 are connected in parallel with series-connected third magnetoresistance effect element MR3 and fourth magnetoresistance effect element MR4, between power supply terminal Vcc and ground terminal GND. To the point where first magnetoresistance effect element MR1 and second magnetoresistance effect element MR2 are connected to each other, first output terminal V+ is connected. To the point where third magnetoresistance effect element MR3 and fourth magnetoresistance effect element MR4 are connected to each other, second output terminal V− is connected.

First magnetoresistance effect element MR1, second magnetoresistance effect element MR2, third magnetoresistance effect element MR3, and fourth magnetoresistance effect element MR4 are each, for example, a TMR (Tunnel Magneto Resistance) element.

First magnetoresistance effect element MR1, second magnetoresistance effect element MR2, third magnetoresistance effect element MR3, and fourth magnetoresistance effect element MR4 each have a rectangular or substantially rectangular outer shape. First magnetoresistance effect element MR1, second magnetoresistance effect element MR2, third magnetoresistance effect element MR3, and fourth magnetoresistance effect element MR4 have a square or substantially square shape, as a whole. Center 7c of magnetic sensor 7 is located at the center of this square.

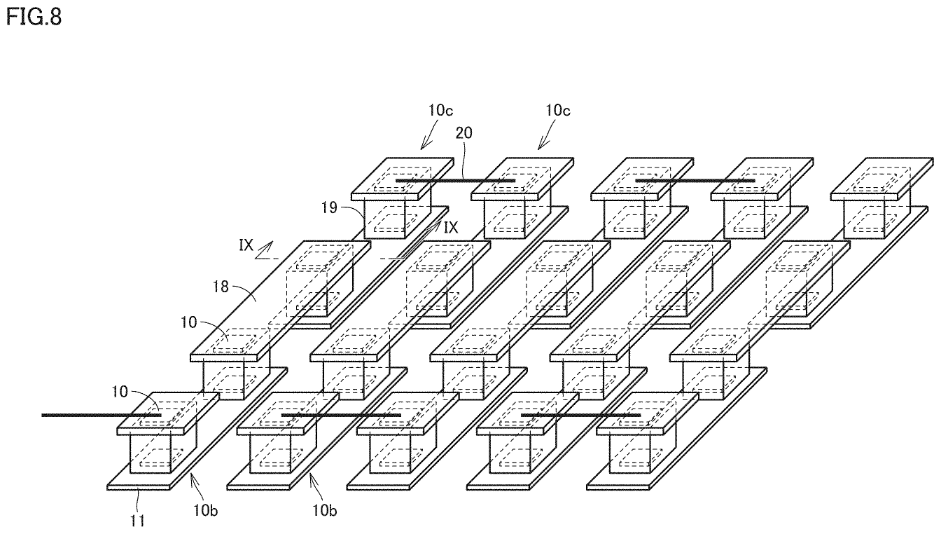

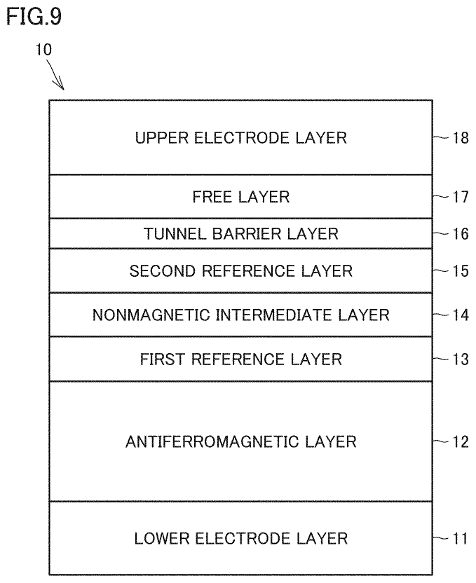

FIG. 8 is a perspective view showing, in an enlarged view, the portion defined by VIII in FIG. 6. FIG. 9 is a cross-sectional view along a line IX-IX in FIG. 8 as seen in the direction of the arrows. As shown in FIG. 8, each of first magnetoresistance effect element MR1, second magnetoresistance effect element MR2, third magnetoresistance effect element MR3, and fourth magnetoresistance effect element MR4 is defined by a plurality of TMR elements 10 that are connected in series. A plurality of TMR elements 10 are arranged in a matrix.

Specifically, a plurality of TMR elements 10 are stacked and connected in series to each other to define a multilayer element 10b. A plurality of multilayer elements 10b are connected in series to each other to define an element column 10c. A plurality of element columns 10c are connected at one end and the other end alternately by a lead 20. Accordingly, in each of first magnetoresistance effect element MR1, second magnetoresistance effect element MR2, third magnetoresistance effect element MR3, and fourth magnetoresistance effect element MR4, a plurality of TMR elements 10 are electrically connected in series.

As shown in FIG. 8, an upper electrode layer 18 of TMR element 10 located on the lower side in multilayer element 10b, and a lower electrode layer 11 of TMR element 10 located on the upper side in multilayer element 10b are integrated into an intermediate electrode layer 19. In other words, upper electrode layer 18 and lower electrode layer 11 of respective TMR elements 10 adjacent to each other in multilayer element 10b are integrated into intermediate electrode layer 19.

As shown in FIG. 9, TMR element 10 in each of first magnetoresistance effect element MR1, second magnetoresistance effect element MR2, third magnetoresistance effect element MR3, and fourth magnetoresistance effect element MR4 has a multilayer structure including lower electrode layer 11, an antiferromagnetic layer 12, a first reference layer 13, a nonmagnetic intermediate layer 14, a second reference layer 15, a tunnel barrier layer 16, a free layer 17, and upper electrode layer 18.

Lower electrode layer 11 includes a metal layer or metal compound layer including Ta and Cu, for example. Antiferromagnetic layer 12 is disposed on lower electrode layer 11, and includes a metal compound layer such as IrMn, PtMn, FeMn, NiMn, RuRhMn, or CrPtMn, for example. First reference layer 13 is disposed on antiferromagnetic layer 12, and includes a ferromagnetic layer such as CoFe, for example.

Nonmagnetic intermediate layer 14 is disposed on first reference layer 13, and includes a layer made from at least one or an alloy of two or more of Ru, Cr, Rh, Ir, and Re, for example. Second reference layer 15 is disposed on nonmagnetic intermediate layer 14, and includes a ferromagnetic layer such as CoFe or CoFeB, for example.

Tunnel barrier layer 16 is disposed on second reference layer 15, and includes a layer made from an oxide including at least one or two or more of Mg, Al, Ti, Zn, Hf, Ge, and Si, such as magnesium oxide, for example. Free layer 17 is disposed on tunnel barrier layer 16, and includes a layer made from CoFeB, or at least one or an alloy of two or more of Co, Fe, and Ni, for example. Upper electrode layer 18 is disposed on free layer 17, and includes a metal layer of Ta, Ru, or Cu, for example.

The magnetization direction of respective pin layers of first magnetoresistance effect element MR1 and fourth magnetoresistance effect element MR4 is opposite by about 180° to the magnetization direction of respective pin layers of second magnetoresistance effect element MR2 and third magnetoresistance effect element MR3.

First magnetoresistance effect element MR1, second magnetoresistance effect element MR2, third magnetoresistance effect element MR3, and fourth magnetoresistance effect element MR4 each may include a magnetoresistance effective element such as, for example, GMR (Giant Magneto Resistance) element or AMR (Anisotropic Magneto Resistance) element, instead of the TMR element.

Regarding the position detector according to Preferred Embodiment 1 of the present invention, Experimental Example 1 is now described to examine a change of the relationship between rotation angle θ (deg) and the detected angle (deg) of magnetic sensor 7, as the ratio between shortest distance L1 between center 7c of magnetic sensor 7 and rotation axis C and shortest distance L2 between center 6c of position detecting magnet 6 and rotation axis C varies.

In Experimental Example 1, a change of the relationship between rotation angle θ and the detected angle of magnetic sensor 7 was examined for 11 different ratios: L1/L2=about 0, about 0.08, about 0.16, about 0.24, about 0.32, about 0.4, about 0.48, about 0.56, about 0.64, about 0.72, and about 0.8. It was supposed that, to the magnetoresistance effect element of magnetic sensor 7, a magnetic field to be detected of about 10 mT or more, for example, which was a saturation magnetic field of the magnetoresistance effect element, was applied from position detecting magnet 6, for any positional relation.

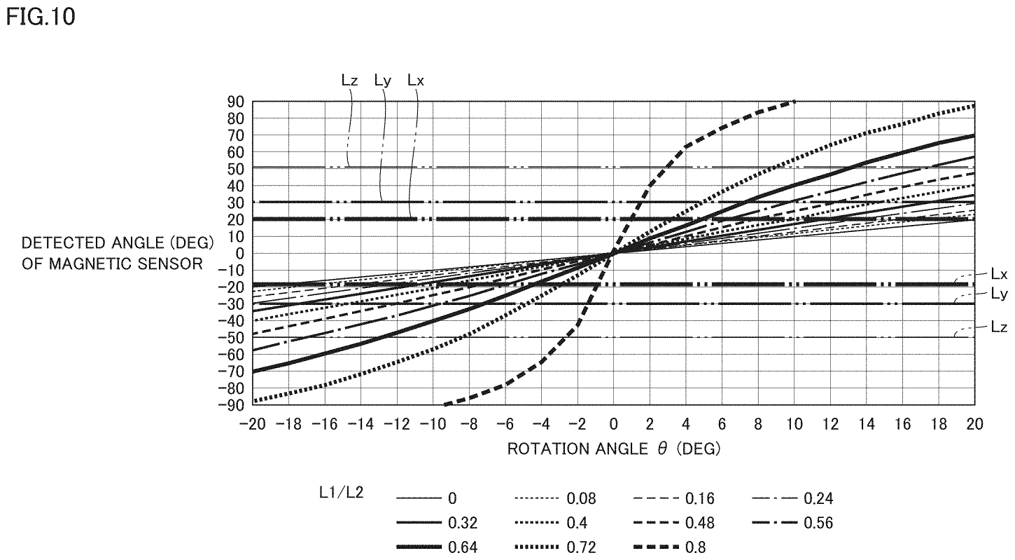

FIG. 10 is a graph showing the results of Experimental Example 1. In FIG. 10, the vertical axis represents the detected angle (deg) of the magnetic sensor and the horizontal axis represents rotation angle θ (deg). Straight lines Lx representing a detected angle of about ±20° of the magnetic sensor, straight lines Ly representing a detected angle of about ±30° of the magnetic sensor, and straight lines Lz representing a detected angle of about ±50° of the magnetic sensor are each indicated by a two-dot chain line.

As shown in FIG. 10, as L1/L2 increases, the detected angle of magnetic sensor 7 with respect to rotation angle θ increases and the range in which the output of magnetic sensor 7 has linearity narrows.

A linearity error rate of the output of the magnetic sensor is defined. FIG. 11 is a graph for illustrating an error rate of the output of the magnetic sensor. In FIG. 11, the vertical axis represents the detected angle (deg) of magnetic sensor 7 and the horizontal axis represents rotation angle θ (deg). In FIG. 11, an actually measured output is indicted by a solid line and an assumed output is indicated by a two-dot chain line.

The assumed output is determined by performing linear approximation of an actually measured output in an intended measurement range of the detected angle of magnetic sensor 7. Specifically, the assumed output is determined by performing linear approximation of rotation angle θ and the actually measured output to a linear function using the least-squares method.

The linearity error rate of the output of magnetic sensor 7 is defined as the ratio of the difference between the actually measured output and the assumed output, relative to the full scale of the output that is the distance between the maximum value and the minimum value of the output corresponding to the intended measurement range of the detected angle of magnetic sensor 7.

As shown in FIG. 10, the linearity error rate of the output of magnetic sensor 7 is about 0.06% when the intended measurement range of the detected angle of magnetic sensor 7 is the range of about ±20° between straight lines Lx, about 0.2% when the intended measurement range of the detected angle of magnetic sensor 7 is the range of about ±30° between straight lines Ly, and about 1.0% when the intended measurement range of the detected angle of magnetic sensor 7 is the range of about ±50° between straight lines Lz.

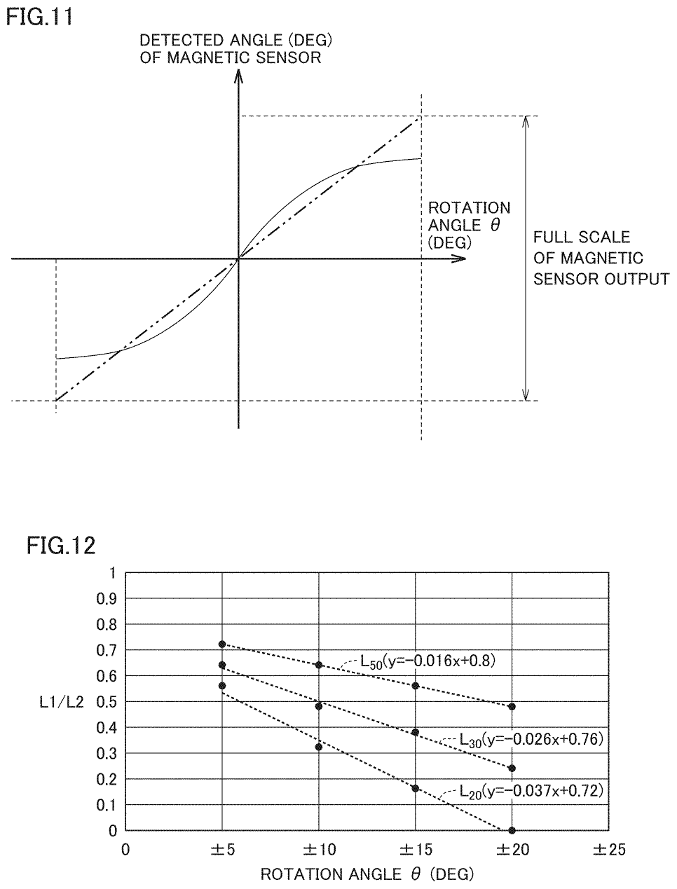

FIG. 12 is a graph showing a possible range of each of the rotation angle and L1/L2, depending on a required linearity error rate of the output of the magnetic sensor, in an intended measurement range of the detected angle of the magnetic sensor, according to Experimental Example 1. In FIG. 12, the vertical axis represents L1/L2 and the horizontal axis represents rotation angle θ (deg).

On straight line L₂₀ indicated by approximation formula y=−0.037x+0.72, a linearity error rate of the output of magnetic sensor 7 of about 0.06% or less can be achieved in an intended measurement range of about ±20° of the detected angle of magnetic sensor 7. On straight line L₃₀ indicated by approximation formula y=−0.026x+0.76, a linearity error rate of the output of magnetic sensor 7 of about 0.2% or less can be achieved in an intended measurement range of about ±30° of the detected angle of magnetic sensor 7. On straight line L₅₀ indicated by approximation formula y=−0.016x+0.8, a linearity error rate of the output of magnetic sensor 7 of about 1.0% or less can be achieved in an intended measurement range of about ±50° of the detected angle of magnetic sensor 7.

Thus, in the region where the relationship −0.026×θ+0.76≤L1/L2≤−0.016×θ+0.8 is satisfied, which is the region between straight line L₅₀ and straight line L₃₀, a linearity error rate of the output of magnetic sensor 7 of about 0.2% or more and about 1.0% or less can be achieved in an intended measurement range of about ±30° or more and about ±50° or less of the detected angle of magnetic sensor 7.

In the region where the relationship −0.037×θ+0.72≤L1/L2≤−0.026×θ+0.76 is satisfied, which is the region between straight line L₃₀ and straight line L₂₀, a linearity error rate of the output of magnetic sensor 7 of about 0.06% or more and about 0.2% or less can be achieved in an intended measurement range of about ±20° or more and about ±30° or less of the detected angle of magnetic sensor 7.

In the region where the relationship 0≤L1/L2≤−0.037×θ+0.72 is satisfied, which is the region extending downward from straight line L₂₀, a linearity error rate of the output of magnetic sensor 7 of about 0.06% or less can be achieved in an intended measurement range of about ±20° or less of the detected angle of magnetic sensor 7.

Thus, with the position detector according to Preferred Embodiment 1 of the present invention, the position detection range, which is an intended measurement range of the detected angle of magnetic sensor 7, as well as the position detection accuracy, which is the linearity error rate of the output of magnetic sensor 7, can be improved with a simple configuration, by the arrangement of magnetic sensor 7 in the XZ plane including magnetization direction M passing through center 6c of position detecting magnet 6 located at reference position B, and the axial direction of rotation axis C.

In the position detector according to Preferred Embodiment 1 of the present invention, magnetic sensor 7 includes a plurality of magnetoresistance effect elements defining a bridge circuit. Accordingly, a magnetic field to be detected that is applied in the direction along the upper surface of sensor substrate 7s can be detected.

The position detector may be used for the region where the relationship 0≤L1/L2≤−0.016×θ+0.8 is satisfied, which is the region extending downward from straight line L₅₀, or the region where the relationship 0≤L1/L2≤−0.026×θ+0.76 is satisfied, which is the region extending downward from straight line L₃₀.

### Preferred Embodiment 2

In the following, a position detector according to Preferred Embodiment 2 of the present invention is described. The position detector according to Preferred Embodiment 2 of the present invention differs from the position detector according to Preferred Embodiment 1 of the present invention, only in terms of the arrangement of the position detecting magnet and the magnetic sensor, and therefore, the description of the same or similar configuration to the position detector according to Preferred Embodiment 1 of the present invention is not herein repeated.

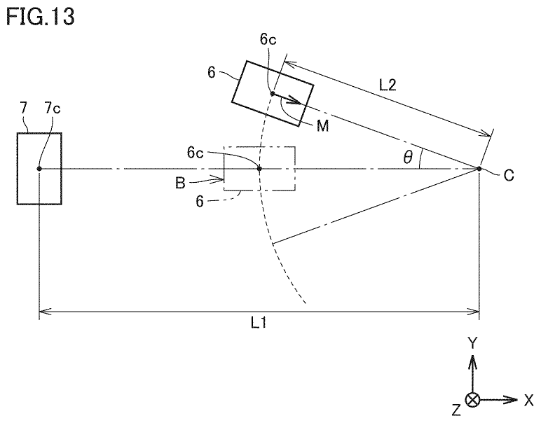

FIG. 13 shows a positional relationship, as seen in the axial direction of the rotation axis, between a position detecting magnet and a magnetic sensor in the position detector according to Preferred Embodiment 2 of the present invention. As shown in FIG. 13, in the position detector according to Preferred Embodiment 2 of the present invention, the relationship L1>L2 is satisfied.

Regarding the position detector according to Preferred Embodiment 2 of the present invention, Experimental Example 2 is now described to examine change of the relationship between rotation angle θ (deg) and the detected angle (deg) of magnetic sensor 7, as the ratio between shortest distance L1 between center 7c of magnetic sensor 7 and rotation axis C and shortest distance L2 between center 6c of position detecting magnet 6 and rotation axis C varies.

In Experimental Example 2, change of the relationship between rotation angle θ and the detected angle of magnetic sensor 7 was examined for 20 different ratios: L1/L2=about 1.28, about 1.36, about 1.44, about 1.52, about 1.6, about 1.68, about 1.76, about 1.84, about 1.92, about 2, about 2.08, about 2.16, about 2.24, about 2.32, about 2.4, about 2.48, about 2.56, about 2.64, about 2.72, and about 2.8. It was supposed that, to the magnetoresistance effect element of magnetic sensor 7, a magnetic field to be detected of about 10 mT or more, for example, that was a saturation magnetic field of the magnetoresistance effect element, was applied from position detecting magnet 6, for any positional relationship.

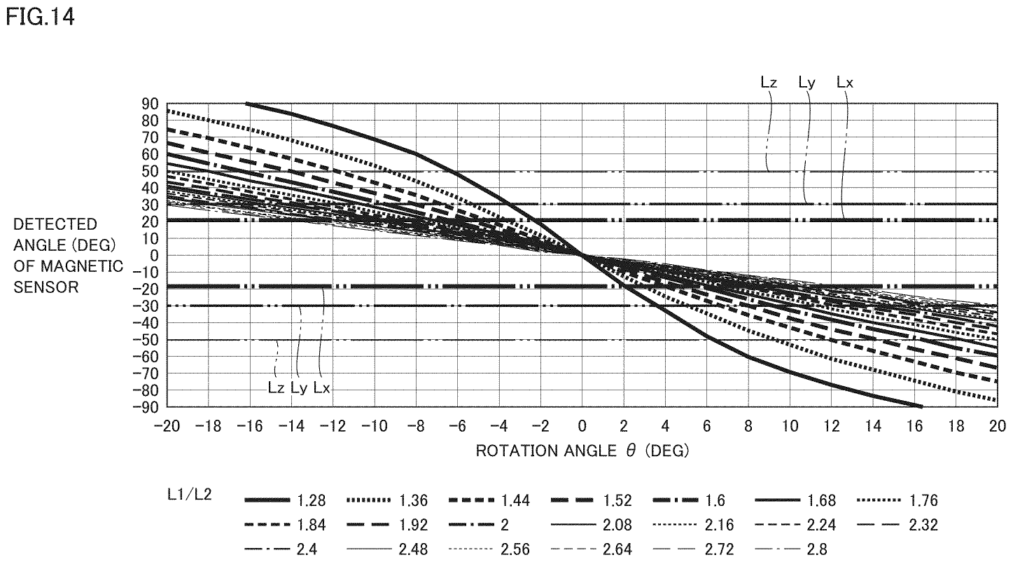

FIG. 14 is a graph showing the results of Experimental Example 2. In FIG. 14, the vertical axis represents the detected angle (deg) of the magnetic sensor and the horizontal axis represents rotation angle θ (deg). Straight lines Lx representing a detected angle of about ±20° of the magnetic sensor, straight lines Ly representing a detected angle of about ±30° of the magnetic sensor, and straight lines Lz representing a detected angle of about ±50° of the magnetic sensor are each indicated by a two-dot chain line.

As shown in FIG. 14, as L1/L2 increases, the detected angle of magnetic sensor 7 with respect to rotation angle θ deceases and the range in which the output of magnetic sensor 7 has linearity widens.

As shown in FIG. 14, the linearity error rate of the output of magnetic sensor 7 is about 0.06% when the intended measurement range of the detected angle of magnetic sensor 7 is the range of about ±20° between straight lines Lx, about 0.2% when the intended measurement range of the detected angle of magnetic sensor 7 is the range of about ±30° between straight lines Ly, and about 1.0% when the intended measurement range of the detected angle of magnetic sensor 7 is the range of about ±50° between straight lines Lz.

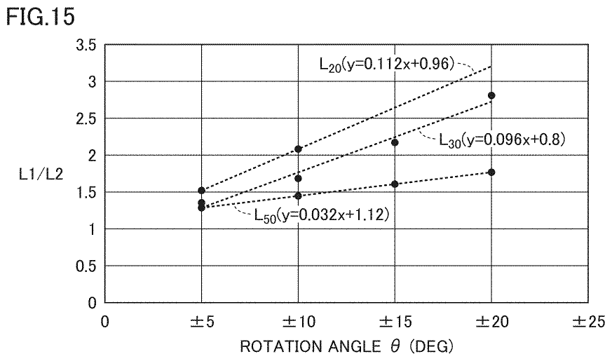

FIG. 15 is a graph showing a possible range of each of the rotation angle and L1/L2, depending on a required linearity error rate of the output of the magnetic sensor, in an intended measurement range of the detected angle of the magnetic sensor, according to Experimental Example 2. In FIG. 15, the vertical axis represents L1/L2 and the horizontal axis represents rotation angle θ (deg).

On straight line L₂₀ indicated by approximation formula y=0.112x+0.96, a linearity error rate of the output of magnetic sensor 7 of about 0.06% or less can be achieved in an intended measurement range of about ±20° of the detected angle of magnetic sensor 7. On straight line L₃₀ indicated by approximation formula y=0.096x+0.8, a linearity error rate of the output of magnetic sensor 7 of about 0.2% or less can be achieved in an intended measurement range of about ±30° of the detected angle of magnetic sensor 7. On straight line L₅₀ indicated by approximation formula y=0.032x+1.12, a linearity error rate of the output of magnetic sensor 7 of about 1.0% or less can be achieved in an intended measurement range of about ±50° of the detected angle of magnetic sensor 7.

Thus, in the region where the relationship 0.032×θ+1.12≤L1/L2≤0.096×θ+0.8 is satisfied, which is the region between straight line L₅₀ and straight line L₃₀, a linearity error rate of the output of magnetic sensor 7 of about 0.2% or more and about 1.0% or less can be achieved in an intended measurement range of about ±30° or more and about ±50° or less of the detected angle of magnetic sensor 7.

In the region where the relationship 0.096×θ+0.8≤L1/L2≤0.112×θ+0.96 is satisfied, which is the region between straight line L₃₀ and straight line L₂₀, a linearity error rate of the output of magnetic sensor 7 of about 0.06% or more and about 0.2% or less can be achieved in an intended measurement range of about ±20° or more and about ±30° or less of the detected angle of magnetic sensor 7.

In the region where the relationship 0.112×θ+0.96≤L1/L2 is satisfied, which is the region extending upward from straight line L₂₀, a linearity error rate of the output of magnetic sensor 7 of about 0.06% or less can be achieved in an intended measurement range of about ±20° or less of the detected angle of magnetic sensor 7.

Thus, with the position detector according to Preferred Embodiment 2 of the present invention, the position detection range, which is an intended measurement range of the detected angle of magnetic sensor 7, as well as the position detection accuracy, which is the linearity error rate of the output of magnetic sensor 7, can be improved with a simple configuration, by the arrangement of magnetic sensor 7 in the XZ plane including magnetization direction M passing through center 6c of position detecting magnet 6 located at reference position B, and the axial direction of rotation axis C.

The position detector may be used for the region where the relationship 0.032×θ+1.12≤L1/L2 is satisfied, which is the region extending upward from straight line L₅₀, or the region where the relationship 0.096×θ+0.8≤L1/L2 is satisfied, which is the region extending upward from straight line L₃₀.

Features that can be combined in the above description of the preferred embodiments may be combined with each other.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A position detector comprising:
an optical reflector rotatable about a rotation axis;
a position detecting magnet on the optical reflector and having a magnetization direction orthogonal or substantially orthogonal to an axial direction of the rotation axis; and
a magnetic sensor that is fixed and operable to detect a magnetic field applied from the position detecting magnet that makes relative movement as the optical reflector is rotated; wherein
rotation of the optical reflector enables the position detecting magnet to pass through a reference position where the rotation axis, a center or approximate center of the magnetic sensor, and a center or approximate center of the position detecting magnet are located in order on a straight line, as seen in the axial direction; and
the magnetic sensor is in a plane that includes the magnetization direction passing through the center or approximate center of the position detecting magnet located at the reference position, and the axial direction.

2. The position detector according to claim 1, wherein the magnetic sensor includes a plurality of magnetoresistance effect elements defining a bridge circuit.

3. The position detector according to claim 1, wherein a relationship −0.026×θ+0.76≤L1/L2≤−0.016×θ+0.8 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

4. The position detector according to claim 1, wherein a relationship −0.037×θ+0.72≤L1/L2≤−0.026×θ+0.76 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

5. The position detector according to claim 1, wherein a relationship 0≤L1/L2≤−0.037×θ+0.72 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

6. The position detector according to claim 1, wherein a relationship 0.032×θ+1.12≤L1/L2≤0.096×θ+0.8 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

7. The position detector according to claim 1, wherein a relationship 0.096×θ+0.8≤L1/L2≤0.112×θ+0.96 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

8. The position detector according to claim 1, wherein a relationship 0.112×θ+0.96≤L1/L2 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

9. The position detector according to claim 1, wherein the optical reflector is a prism mirror.

10. The position detector according to claim 2, wherein the plurality of magnetoresistance effect elements include four magnetoresistance effect elements defining a Wheatstone bridge circuit.

11. A compact camera module comprising:
the position detector according to claim 1.

12. The compact camera module according to claim 11, wherein the magnetic sensor includes a plurality of magnetoresistance effect elements defining a bridge circuit.

13. The compact camera module according to claim 11, wherein a relationship −0.026×θ+0.76≤L1/L2≤−0.016×θ+0.8 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

14. The compact camera module according to claim 11, wherein a relationship −0.037×θ+0.72≤L1/L2≤−0.026×θ+0.76 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

15. The compact camera module according to claim 11, wherein a relationship 0≤L1/L2≤−0.037×θ+0.72 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

16. The compact camera module according to claim 11, wherein a relationship 0.032×θ+1.12≤L1/L2≤0.096×θ+0.8 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

17. The compact camera module according to claim 11, wherein a relationship 0.096×θ+0.8≤L1/L2≤0.112×θ+0.96 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

18. The compact camera module according to claim 11, wherein a relationship 0.112×θ+0.96≤L1/L2 is satisfied, where L1 is a shortest distance between the center or approximate center of the magnetic sensor and the rotation axis, L2 is a shortest distance between the center or approximate center of the position detecting magnet and the rotation axis, and θ is a rotation angle, about the rotation axis, of the position detecting magnet from the reference position, as seen in the axial direction.

19. The compact camera module according to claim 11, wherein the optical reflector is a prism mirror.

20. The compact camera module according to claim 12, wherein the plurality of magnetoresistance effect elements include four magnetoresistance effect elements defining a Wheatstone bridge circuit.
